(19) United States
(12) Patent Application Publication
(10) Pub. No.: US 2024/0271979 A1
(43) Pub. Date: Aug. 15, 2024

(54) METERING SYSTEM

(71) Applicant: VERMES MICRODISPENSING GMBH, Holzkirchen (DE)

(72) Inventors: Mario FLIESS, München (DE); Simon SCHMIDBERGER, Bruckmühl (DE)

(73) Assignee: VERMES MICRODISPENSING GMBH, Holzkirchen (DE)

(21) Appl. No.: 18/562,677

(22) PCT Filed: May 31, 2022
(86) PCT No.: PCT/EP2022/064801

§ 371 Date: Nov. 20, 2023

(30) Foreign Application Priority Data
Jun. 2, 2021 (DE) 10 2021 114 302.0

(51) Int. Cl. G01F 11/34; G01F 15/00; H10N 30/20

(52) U.S. Cl. CPC G01F 11/34; G01F 15/003; G01F 15/005; H10N 30/20

(57) ABSTRACT

The invention relates to a metering system (1) with a housing (2), a piezo actuator (10) located therein, a fluidic unit (15) with a valve (16), a plunger device (40) for closing the valve (16), and a transmission lever (20) for coupling the piezo actuator (10) to the plunger device (40), wherein the piezo actuator (10) is arranged substantially parallel next to the plunger device (40) in the housing (2), wherein the piezo actuator (10) extends away from the transmission lever (20) substantially in the direction of a side facing the valve (16).

The invention relates to a metering system with a housing, a piezo actuator located therein, a fluidic unit with a valve, a plunger device for closing the valve, and a transmission lever for coupling the piezo actuator to the plunger device.

Metering systems are usually used to meter a medium which is to be metered, typically a fluid to semifluid metering substance, in a targeted manner, for example by a dropwise or respectively metering point-like delivery of the metering medium by means of the plunger device via a valve of the metering system. With such a delivery therefore for example a metering point or respectively “dab” (drop) can be placed at a location on a workpiece in a single metering step (expressed very simply on a single opening movement of the plunger device).

Within the so-called “micrometering technique” is it furthermore often necessary that very small quantities of the metering medium or respectively metering substance are applied in a precisely accurate manner onto a target surface, and namely in a contactless manner, i.e. without a direct contact between the metering system and a target surface. Such a contactless method is frequently also designated as a “jet method”. A typical example for this is the metering of adhesive dots, soldering pastes etc. in the equipping of circuit boards or other electronic elements, or the application of converter materials for LEDs.

From EP 1 414 080 A2 for example a piezoelectric actuator system or respectively positioning system with a piezo actuator and an integrated lever transmission is known, in which the piezo actuator extends away from the transmission lever on a side facing away from the valve. This arrangement has the disadvantage that the actuator system, in a design-related manner, is lengthened or respectively must be disadvantageously long.

It is therefore an object of the present invention to overcome the disadvantages of the prior art and to indicate a particularly compact metering system.

This problem is solved by a metering system according to claim 1.

As mentioned in the introduction, the metering system comprises a housing. The housing is to be understood to mean both a predominantly closed outer casing, and also inner structures in which the components, located therein, are accommodated in a suitable manner.

One of these components is the elongated piezo actuator which was already mentioned in the introduction. This serves to generate a pulse or respectively a metering movement, which is transferred to the plunger device via the transmission lever, in order to open or close the valve. For this, the piezo actuator can be advantageously fitted into the housing. Here, it can preferably also have an encapsulation, i.e. the actual piezo or respectively piezo stack can be encapsulated, in order to protect it from moisture. The encapsulated piezo actuator can then be cooled more effectively.

The mentioned valve of the fluidic unit can concern in particular a so-called “jet valve”, therefore a valve which is suitable for “jetting” or respectively can be operated in a jet method. With this operating mode, the plunger device serves primarily as an ejection element, i.e. on the movement of the plunger towards a valve seat or respectively sealing seat of the valve, the metering material or respectively the metering substance is ejected by the plunger. Additionally or alternatively, a portion of the plunger device can also function, in its function type, as an actual closure element, which closes the valve respectively in the course of the metering movement, by the plunger pressing in its end position into the valve seat. When the metering material, due to other forces, e.g. gravity and/or an increased pressure in the valve with respect to the environment, can exit from the valve, can therefore also be metered, the valve is opened and closed again after delivery of the desired metering quantity, by simply withdrawing the plunger from the valve seat. Depending on the application, the plunger device can be operated here in the different function types by the plunger of the plunger device serving as closure element of valve and/or as ejection element (“jetting”). Both function types can have practical relevance.

The said transmission lever is furthermore accommodated in the housing. This serves for coupling the piezo actuator to the plunger device. The transmission lever can, in turn, be mounted in a lever bearing of the housing via a shaft, so that the transmission lever can be tilted relative to the shaft or respectively tilting axis.

The shaft can concern, for example, a linear contact or respectively roller bearing, as is already known from EP 1 414 080 A2.

The fluidic unit with the valve, mentioned in the introduction, can be configured for example so that it can be coupled to the housing, in order to supply the metering system substantially with metering substance, so that the metering substance can then, in turn, be delivered by means of the plunger device through the valve in desired metering. Except for the parts of the plunger device (as is further explained below), the fluidic unit comprises substantially all components which serve for the provision, temperature control etc. of the metering substance.

The piezo actuator is arranged, in particular aligned, here substantially next to the plunger device in the housing. “Substantially next to” means that the two components, viewed spatially, lie closely together.

According to the invention, the piezo actuator extends away from the transmission lever substantially in the direction of the valve in the direction of a side facing the valve. In other words the piezo actuator and plunger device run next to one another or respectively substantially parallel to one another in the housing away from one of the two lever arms of the transmission lever.

At this point, for the sake of simplicity, it is pointed out that in the following, without loss of generality, a direction to the valve is also designated as a direction downwards, and a direction away from the valve to the transmission lever is designated as a direction upwards. Relative directional information such as “above”, “below”, etc. (more are also listed further below) are therefore to be understood accordingly, although the metering system is not restricted to a metering in this arrangement.

The arrangement according to the invention enables a particularly compact construction, whereby the metering system as a whole can be distinctly shorter than is possible with the solutions known from the prior art. Here, it utilizes the space in the housing in an optimum manner, so that the longer components, such as the elongated plunger device or the piezo actuator do not require space unnecessarily, i.e. for example add substantially with regard to length, as was the case hitherto in the constructions of the prior art.

In addition, the construction according to the invention creates additional space lengthwise, which—as is additionally explained further below—can be used such that the essential closure part of the entire metering system, namely a plunger of the plunger device, which as stated functions as closure element or as ejection element according to the selected function type in which the metering system is operated, can be installed easily and quickly for the customer in an exchangeable manner. In addition, the metering system, which in its construction type is originally designed for a so-called “normally closed” operation, i.e. “operation or respectively metering operation which is closed in the initial position”, can thus, with the same length, also use components which are now able to be used both for normally opened and also for normally closed metering systems (for instance the plunger and the fluidic unit). With a normally opened or respectively open (“normally-open”) valve in the currentless state of the metering system, the closure element—if no voltage is applied at the metering system—is not pressed into the sealing seat in the valve, but rather has a small distance with respect thereto. If such a metering system is powered up into a metering operation, i.e. switched on, the metering system is firstly acted upon with voltage so that the closure element is then closed in an initial starting position for the metering operation.

Here, before each metering pulse, the closure element can then be arranged in the valve seat in the valve or respectively in a nozzle of the valve and, on a metering movement, can be raised minimally from this initial starting position, and subsequently lowered again, so that depending on the position and opening duration, metering substance can exit accordingly. In the jet method, metering substance is additionally ejected here, because the plunger then functions, as stated, as an ejection element and ejects metering substance when it moves, as ejection element, to the valve seat for closing.

Irrespective of the function type of the plunger, it is often advantageous if the metering substance has a sufficient viscosity, so that owing to its viscosity it does not flow out or run out from the valve by itself, even when the valve is opened. Nevertheless, sometimes it can not be avoided that low-viscosity metering substances are also to be metered.

In a metering operation which is closed in the initial starting position, the closure element, whenever metering is not taking place, e.g. in the currentless switched state or in the case of breakdown or fault, is preferably arranged automatically by a suitably adjusted spring owing to spring tension in a so-called valve seat or respectively sealing seat in the valve. This means that the valve is then actually closed sufficiently tightly with the closure element arranged therein, so that even a very fluid, low-viscosity metering substance can not exit. This metering operation is therefore suitable precisely for particularly fluid metering substances or when the metering substance, as mentioned, is to be metered from the valve with additional pressure.

Further, particularly advantageous embodiments and further developments of the invention will emerge from the dependent claims and from the following description, wherein also individual features of various example embodiments or respectively variants can be combined to new example embodiments or respectively variants.

Preferably, the transmission lever can extend transversely to an extent direction of the piezo actuator and an extent direction of the plunger device. This means that the transmission lever runs from the elongated plunger device transversely in a transversely-running extent direction to the elongated piezo actuator.

The extent directions of the piezo actuator and of the plunger device can preferably be substantially identical.

By definition, “transverse” preferably designates almost at right-angles to a line assumed as length. In this respect, in so far as the extent directions of the plunger device and of the piezo actuator are identical, “transverse” is understood here to mean preferably substantially at right-angles to the extent directions of the two components. In so far as the extent directions of the piezo actuator and of the plunger device slightly diverge or respectively converge, therefore the components do not run exactly parallel, transverse can also mean only from the one component transversely to other component, therefore for example slightly obliquely or respectively at an angle deviating from 90° insignificantly only by a few degrees.

Particularly preferably, the transmission lever can therefore extend substantially perpendicularly to an extent direction of the piezo actuator and an extent direction of the plunger device.

By the transmission lever extending transversely, preferably substantially perpendicularly, to an extent direction of the piezo actuator and an extent direction of the plunger device, the pulse transmission of the deflection or respectively of the pulse of the piezo actuator via the transmission lever to the plunger device is maximized. The piezo actuator (in so far as, as provided, a configuration of the metering system is concerned, in which the valve in the currentless state is closed by the plunger device) can thus exert an “opening moment” onto the plunger device, for metering in a current-carrying metering operation via the transmission lever, or respectively can transfer a force to the plunger device, which leads to a movement of the plunger device away from the valve, therefore to a type of “lifting movement”, as is explained more precisely further below. In addition, the housing can be configured in a very compact manner, particularly preferably substantially in a cuboid-shaped manner, as the larger, elongated components extend substantially only in two orthogonal directions to one another, and thus protuberances or respectively projections through components running obliquely thereto can be largely prevented.

Alternatively or additionally, the piezo actuator, via the transmission lever with the plunger device, can be tensioned relative to the housing by means of a spring arrangement. A spring arrangement means at least one spring element such as e.g. a pretensioning spring, in particular a compression coil spring, which tensions or respectively pretensions the transmission lever directly or indirectly against the surrounding housing of the metering system.

This makes provision, as has also already been mentioned in EP 1 414 080 A2, that the metering system is not relaxed in the case of forces acting externally onto the metering system, and the components are thus held together in a suitable manner.

The transmission lever can preferably be fitted in a tiltable manner on a tilting axis in the form of a shaft on a side of the shaft facing the piezo actuator. This means that the transmission lever is held between the shaft and the piezo actuator.

The shaft, in turn, can preferably be fastened respectively on the end side in a lever bearing on a side or respectively upper side facing away from the valve. This means that the shaft is mounted e.g. in a non-rotatable manner and the transmission lever tilts against the non-rotatable shaft.

Alternatively, for example, a trough could be recessed or formed in in the transmission lever on a lever side facing away from the piezo actuator, into which trough the shaft could e.g. be pressed in in a non-rotatable manner, for fastening. The shaft would then rotate in lateral openings in the lever bearing.

Basically, the transmission lever could have, for example, two substantially symmetrical lever arms, therefore at least of equal length, i.e. be mounted substantially centrally around the tilting axis.

The transmission lever can preferably be mounted eccentrically and can be configured asymmetrically, i.e. can have a short and a lever arm relatively longer thereto. Such a transmission lever is explained more precisely further below with the aid of a preferred example embodiment.

When the concern is with a transmission lever with a short and a lever arm relatively longer thereto, the transmission lever—in order to save space—can be fitted particularly preferably eccentrically in a tiltable manner at the previously mentioned end portion.

Here, for opening the valve, the piezo actuator can preferably stand close to the tilting axis at the long lever arm at an actuator engagement point at right angles to the tilting axis at the transmission lever with the formation of a roller bearing. Thereby, the transmission lever, in operation, on a deflection of the piezo actuator, together with the plunger device, lying on the long lever arm remotely from the tilting axis, therefore further away from the tilting axis than the actuator engagement point close to the tilting axis, can be moved in the direction of an opened valve position away from the valve, or respectively moved out from a tight valve seat. The relative terms “close to the tilting axis” and “remote from the tilting axis” refer here respectively to points or respectively positions in a longitudinal direction of the transmission lever relative to the tilting axis, at which the transmission lever is tiltably mounted. Close to the tilting axis means accordingly simply a location or respectively a pint along the longitudinal direction or respectively the above-mentioned transversely-running extent direction of the transmission lever, which point lies nearer to the tilting axis than a point remote from the tilting axis.

The plunger device can preferably be formed from at least two rod elements which are tensioned with respect to one another. Tensioned with respect to one another means that a force acts on the rod elements which presses the rod elements against one another permanently, so that these are permanently in pressure contact.

Here, the plunger device can have particularly preferably on the lever side a transmission element as a first rod element. In the following, the transmission element is also designated as “connecting rod” or respectively “con rod”, as it preferably functions as a type of “connecting rod”, as will become clearer in further course, therefore carries out a slight circular path movement.

Furthermore, the plunger device can have particularly preferably on the valve side a closure element as a second rod element. The closure element is also designated in the following as “valve plunger rod” or respectively abbreviated as “plunger”, as is usual in this technical field.

With the said combination of features it is achieved that the movement of the transmission lever, which movement, due to construction, comprises both axial and also transverse components, is not transferred directly to the valve-side closure element of the plunger device, but only indirectly to the closure element via the lever-side transmission element, as the transmission element is in pressure contact with a lever-side plunger head of the closure element or respectively plunger. Owing to the pure pressure contact, and as the closure element can advantageously still be guided predominantly axially, almost no transverse components are transferred to the closure element on the transmission of the movement of the transmission element.

The valve-side rod part of the plunger device, therefore the closure element, can thus carry out a purely axial movement as free as possible of the said transverse components, in order, for example in the currentless or respectively voltage-free state of the metering system, to securely seal the valve with a valve-side plunger tip of the closure element or respectively plunger in a so-called valve seat or respectively sealing seat in the valve. This facilitates the closure element being able to be guided or respectively pressed as exactly as possible straight into the valve seat, and reduces the risk that possibly a sufficient sealing of the valve can no longer be guaranteed for a particularly low-viscous metering substance.

Furthermore, the division of the plunger device into two rod parts, tensioned with respect to one another, assists that the transmission element, which is in fact in direct contact with the transmission lever, can describe a connecting rod movement, which minimizes the wear of a potential friction point between plunger device and transmission lever, which would be present on an axial forced guidance.

In addition, the valve-side part, which according to experience is exposed to the most wear, can thus be exchanged in an isolated or respectively separate manner, without the metering system having to be dismantled for this or respectively the plunger device having to be exchanged as a whole.

There are various possibilities for the configuration of the spring arrangement.

The spring arrangement can preferably have several springs or respectively spring elements for the sprung tensioning of the plunger device. It can comprise, for example, a spring or respectively a spring element, which presses the plunger device on the valve side, i.e. on the side facing the valve in the installed state, or on a side of the transmission lever facing away from the valve, against the transmission lever, so that these components are in pressure contact with respect to one another. Additionally or alternatively, it could have, for example, a spring which presses the plunger device in a currentless state of the metering system into an opened valve position just above a valve seat, i.e the plunger device does not close the valve of the fluidic unit in the currentless state. As already mentioned above, such a normally opened mode of operation of the metering system presents itself when the metering medium is in any case for example correspondingly viscous or respectively high-viscous and thus also does not already flow out by itself from the opened valve opening under gravity.

The spring arrangement can, however, also be configured so that the metering system, in a currentless switched state, has a closed valve, i.e. the plunger device, or respectively the plunger of the plunger device, is pressed into the valve seat. Such a normally closed mode of operation of the metering system presents itself, as mentioned, in the case of lower-viscous media, which would tend to already exit or respectively run out from the opened valve owing to gravity.

Further preferably, the spring arrangement can accordingly comprise at least one opening spring arrangement for opening the valve and at least one closure spring arrangement for closing the valve, wherein the closure spring arrangement has a greater, e.g. double, spring rate and/or pretensioning force relative to the opening spring arrangement.

Such a spring arrangement makes provision that the valve always is and remains closed in the currentless state, because the spring force of the closure spring predominates with respect to the oppositely acting spring force of the opening spring. The valve begins to open automatically or respectively unavoidably only starting from a point at which the transmission lever together with the opening spring at least equalizes the force of the closure spring owing to a pulse of the piezo actuator. In other words, the opening spring opens the valve automatically when the transmission lever presses the closure spring away from the valve.

The closure spring arrangement can comprise here simply a single closure spring which has the greater or respectively double spring rate and/or pretensioning force with respect to the opening spring arrangement (which can also have only one single opening spring). Instead of a closure spring with a double spring rate and/or pretensioning force relative to the opening spring, the spring arrangement can, however, particularly preferably also comprise two, e.g. substantially identically constructed, closure springs, operating in the same direction but contrary to the opening spring, with respectively half in first approximation with respect to a single closure spring, but otherwise the same spring rate and pretensioning rate with respect to the other closure spring. In the following—as corresponds to a preferred variant—mention will always be made to two closure springs (with half spring rate and pretensioning force) instead of one closure spring (with double spring rate and pretensioning force). This is not intended to have a limiting effect in so far as in the following always at least two closure springs are required. Basically, in the following also the two closure springs can always be replaced by a corresponding spring, if applicable at another position, unless otherwise noted in this respect. This is because a closure spring which is double as strong has, in first approximation, the same function as two half as strong closing springs. An advantage of two springs compared to a single one lies in that they are able to be used in a more variable manner, in particular at various positions, as is explained more precisely further below.

Very particularly preferably, the spring arrangement can comprise two closure springs operating in the same direction but contrary to the opening spring, with respectively substantially the same spring rate and pretensioning force in first approximation to the opening spring, so that therefore almost double the closure spring force opposes a particular opening spring force.

At this point it is to be mentioned that the spring arrangement can basically comprise various spring types, such as e.g. tension springs, wave springs, plate springs, torsion springs etc. Particularly preferably, the spring arrangement can comprise compression coil springs. Possible forms for such compression coil springs or respectively compression springs, which present themselves particularly, are for example cylindrical, cone-shaped, barrel-shaped, waist-shaped compression springs.

Preferably, the opening spring arrangement or respectively the opening spring (in the following, the opening spring arrangement will also—without loss of generality—designated in abbreviated form as opening spring) fit the closure element, already mentioned above, in the housing in a resilient manner such that a force acts on the closure element in order to bring the closure element in the direction of an opened valve position.

Here, the closure springs can tension the transmission element resiliently in the housing such that a contrary force—at least somewhat greater in relation to the opening spring—acts on the transmission element, in order to bring the transmission element against the closure element and thus to bring the closure element in the direction of a closed valve position. As already indicated above, the construction of the resiliently mounted plunger device makes it possible that components can be used which now are able to be used both for normally opened and also for normally closed metering systems (for instance the plunger and the fluidic unit).

As already mentioned in EP 1 414 080 A2, the spring arrangement of the metering system can also comprise here at least one radially exterior large compression coil spring, which surrounds in a space-saving manner at least one of the already mentioned closing compression coil springs which are smaller in comparison. By the compression coil spring, also designated in the following as pretensioning spring, due to its function, the transmission lever can be pretensioned remotely with respect to its tilting axis on the long lever arm, therefore further away from the tilting axis than the actuator engagement site close to the tilting axis on the same, separately relative to the housing against the piezo actuator. By means of the pretensioning of the piezo actuator it is achieved that the latter, after a deflection, can be returned more quickly again fully into its initial position.

In contrast to EP 1 414 080 A2, the transmission lever can preferably be pretensioned or respectively the pretensioning can be set such that the valve is closed by means of the plunger tip in a valve seat of the valve in the currentless initial state of the metering system, by at least a plunger tip of the valve-side plunger of the plunger device being positioned.

Various possibilities also exist for the further configuration of the plunger device.

The transmission element of the plunger device can preferably, in turn, comprise two parts which are able to be coupled to one another. These can be coupled in a force-fitting and/or form-fitting manner. For example, the parts can be pressed to one another.

Alternatively or additionally, the parts can be glued to one another.

Further preferably, the parts can also be thermally shrunk or respectively coupled by means of thermal shrinking.

Particularly preferably, furthermore the transmission element can comprise a rod part as one part and a head sleeve part as a further part.

Here preferably an elongated, in particular cylindrical, rod part of the transmission element can stand or respectively lie on the valve side, i.e. at the end facing the valve in the installed state, and can extend from there to a head sleeve part on the other side of the transmission lever. For example, the rod part can run remotely from the tilting axis on the long lever arm of the transmission lever substantially through the transmission lever or closely past.

Preferably, the rod part, guided with some surrounding play, can extend through a through-opening or respectively bore in the transmission lever.

Alternatively or additionally, the head sleeve part can preferably have a flange on which on the valve side, i.e. on the flange surface facing the valve in the installed state, the transmission lever stands or respectively lies. Particularly preferably, the flange can be located approximately on half of its longitudinal extent.

A division of the transmission element into several individual parts which in themselves have little complexity, which are only then in turn connected to one another, makes their production as a whole more favourable and, in addition, facilitates this enormously. As already mentioned, the parts can be subsequently connected, e.g by means of thermal pressing, easily to a coupled component. The transmission lever can thus axially deflect the plunger device, guided in a very exact manner, against the force of the two closure springs, in an example embodiment which is later explained further, therefore e.g. it can press upwards, so that the valve, through the force of the opening spring, owing to the counter force of the closure springs, which is temporarily overcome or respectively taken over by the transmission lever, opens automatically or respectively moves into an open valve position.

Preferred possibilities also exist for the arrangement of the plunger device in the housing.

The rod part of the transmission element can preferably be axially guided on the valve side parallel to the piezo actuator in a first housing sleeve portion of a housing sleeve of the housing with relatively close radial surrounding play. This means that the rod part of the transmission element on the valve side close to the transmission lever, i.e. here in a region closely beneath the transmission lever, is also movable slightly laterally, in radial direction in relation to the cylindrical rod of the rod part in the housing sleeve, but can basically be guided axially. The rod part thus moves as much as is possible only in axial direction in a straight line, without significant transverse movement out of the valve out of the valve seat or respectively into the valve into a valve seat.

In contrast, the head sleeve part of the transmission element facing away from the valve can be guided with a relatively wide radial surrounding play. This permits a slight transverse movement or respectively circular path movement of the head sleeve part, which occurs through the contact point to the transmission lever, remote from the tilting axis, to which in turn, as already mentioned several times, a pulse or respectively a type of “torque” is transmitted by the piezo actuator close to the tilting axis. The head sleeve part thus acts like a kind of connecting rod, as is explained more precisely further below.

In other words, the head sleeve part, viewed from the valve, on the other side of the transmission lever, therefore here above in its radial movement can be almost not limited at all, therefore can carry out a full range of movement almost freely, i.e. at least in so far as it can move within the possible movement of the rod part on the valve side, therefore below here, which is guided closely axially relative thereto. This means that it is limited by the length of the rod part in any case to a very small transverse movement or respectively range of movement. This is because if the head sleeve part is moved too far laterally, the rod part abuts below directly against its close surrounding axial guide and thus prevents further transverse movements or respectively transverse deflections (or respectively radial movements) of the head sleeve part.

Preferably, one of the closure springs, in particular e.g. the small compression coil spring which is surrounded by the large compression coil spring, of the spring arrangement can stand or respectively lie at the head sleeve part on a side of the flange facing away from the valve.

The transmission element or respectively the head sleeve part of the transmission element can thus be tensioned between housing and closure element without direct contact to the lever. In addition, this arrangement saves space, as this closure spring is housed in the interior and thus unused region of the pretensioning spring of the piezo lever system, and thus does not lengthen the plunger device of the metering system unnecessarily.

The flange of the head sleeve part can have hemispherically protruding spherical shells for low-wear interlocking between transmission lever and plunger device on the valve side in installed state as intended on the side facing the valve. They can form a bearing together with corresponding spherical caps which are formed, particularly preferably recessed, for this on the transmission lever.

The bearing is also designated in the following as a roller bearing, as the spherical shell surfaces in the spherical caps carry out a slight, particularly friction-free rolling movement, whereby an almost friction-free transition is formed between the slight circular path movement or respectively connecting rod movement of the head sleeve part and the axial movement of the rod part.

Particularly preferably, the spherical shells in the flange of the head sleeve part can be configured in the form of hemispherically recessed spherical caps with spheres pressed in therein. This facilitates the production, as the forming of hemispherically projecting spherical shells can be omitted on one of the components.

Most particularly preferably, the flange of the head sleeve part can comprise a bearing block on the rear side of the contact point at which the above closure spring stands. The bearing block can further project e.g. again in the form of a cuboid in a flange-like manner (in the manner of a “block-shaped chordal quadrilateral”) on the round flange away from the closure spring in the direction towards the transmission lever. Such an additional bearing block on the round flange has the advantage that it offers space in order to form or respectively recess the spherical caps therein. In order to receive the two spherical cap recesses or respectively spherical caps of the transmission lever in a low-wear manner, a bearing face of the bearing block can again in itself be provided with hemispherically recessed spherical caps, in which, again, spheres as pressed in, on which the spherical caps of the transmission lever can roll.

The “interlocking” via the spheres which are pressed into the head sleeve part to the spherical caps in the transmission lever, which is produced by doing this, is only “loosened” in the closed state of the valve, when the plunger or respectively the closure element is raised slightly from the transmission lever through a nozzle- or respectively valve insert in the valve.

Various possibilities also exist for the further configuration of the metering system.

Preferably, a first permanent magnet can be fastened to the plunger device, preferably at the head sleeve part of the transmission element. The permanent magnet can be fastened for example on a front-side end of the plunger device remote from the valve.

Particularly preferably, the permanent magnet can therefore be fastened, in more precise terms, on the head sleeve part of the plunger device, at an end of the plunger device or respectively of the head sleeve part of the plunger device facing away from the transmission lever in the installed state as intended.

Here, a Hall sensor can preferably be arranged lying opposite in the housing, spaced apart by a gap, to this permanent magnet. This sensor can be arranged conveniently e.g. on a board for the controlling etc. of the metering system, which is located above the front-side end of the plunger device, more precisely of the head sleeve part of the plunger device.

By means of the permanent magnet and the Hall sensor, the position of the plunger device with respect to the valve or respectively to the nozzle can be measured and can then be adjusted accordingly. Here, for example, a standardization table can indicate the correlation between a voltage change of the Hall sensor and the underlying distance change. Firstly, before the adjusting of the precise position of the plunger device with respect to the nozzle, the head nozzle part of the transmission element of the plunger device lies at or on the transmission lever, wherein the plunger tip of the plunger does not yet close the nozzle or respectively the valve in the normally closed valve position, without touching it directly. For adjusting a suitable position of the plunger relative to the nozzle, the nozzle is moved in the direction of the plunger until a defined flow change is detected by means of the permanent magnet and the Hall sensor, and thus a defined lifting of the head sleeve part, in particular of the spherical shells from the spherical caps of the transmission lever from the transmission lever is provided. For this, the distance between the nozzle and the plunger tip is reduced by twisting an adjusting nut until the desired voltage change is able to be detected via the Hall sensor. This desired position can subsequently also be monitored continuously in operation.

More precisely, at the start of the adjusting process or respectively “adjust process”, a distance is to be created between nozzle insert and plunger, by the coupling nut or respectively (nozzle) adjusting nut, which is to be further described later by means of an example embodiment, being twisted until it stands in the lowermost adjustable position (greatest distance between nozzle insert and plunger). The adjusting routine or respectively “adjust routine” is then started, and the distance is firstly reduced, and finally the plunger is raised through the nozzle insert until a display in the control unit indicates that the desired position (slight raising from the lever) is reached.

In operation it can consequently always be monitored whether the lever movement component, which without entrainment of the plunger (a gap produced by the slight lifting during the adjusting process or respectively adjust process) changes and/or whether the voltage of the Hall sensor has changed in the closed state, and/or how great the overall change of the Hall sensor signal is with respect to the desired or respectively expected plunger movement. Here also, if required, the control signal can be adapted so that the movement is still equal and hence remains stable also in the case of wear. Thus, a necessary engaging of the user in operation can be prevented for as long as possible, which e.g. increases the machine productivity and reduces maintenance times.

Preferably, a second, here for example smaller, permanent magnet can be arranged on a side of the Hall sensor facing away from the first permanent magnet.

Preferably here the second permanent magnet can comprise a counter magnetic field opposed to the first permanent magnet.

The measurement range of the Hall sensor, which is always divided symmetrically around the zero point, can thus be displaced such that a greater, advantageously its complete, measurement range can be used and it thereby receives a greater sensitivity. This is because the Hall sensor can thus no longer only measure in the positive or in the negative range. Rather, its measurement range is at least partially, preferably completely, displaced into the negative range or, according to the polarity of the magnetic field, into the positive range, and is thus increased.

Alternatively or additionally, a surrounding region around the Hall sensor, particularly preferably including the second permanent magnet, can be magnetically shielded by means of a shield at least on the sides facing away from the first permanent magnet.

The sides facing away from the first permanent magnet mean that the shield can be advantageously opened at least on one side towards the first permanent magnet, so that the head sleeve part can be moved with the first permanent magnet at least on this side into the shield and external possibly intrusive magnetic field influences on the remaining sides can be shielded. For this, the shield can be configured for example substantially in a cuboid-shaped manner or respectively with a cuboid-shaped housing.

Alternatively or additionally, the shield can also consist of a cuboid-shaped component, a soft magnetic lever bearing and/or a soft magnetic component inserted into the lever bearing in the direction of the valve. A soft magnetic component which is inserted into the lever bearing presents itself especially when the lever bearing is made from a more favourable stable material, such as e.g. aluminium etc., which itself does not act in a sufficiently magnetically shielding manner, but provides for the necessary stability.

Advantageously, the upper region above the board, which has already been mentioned, and the frame region surrounding the piezo actuator, can be made from non-magnetic materials, in order to be able to design these to be more favourable and lighter. Generally, measurement errors can be practically prevented by the shield, or respectively interference factors which could influence the measured magnetic field, are minimized.

Preferably, the housing sleeve, already mentioned above, in which the plunger device is guided on the inner side at least in sections, can be mounted adjustably in position externally by means of a spring which is able to be tensioned by a nut, relative to the surrounding housing of the metering system for adjusting a distance between valve and closure element (typically also designated as “nozzle-plunger distance”). The distance can be adjusted very easily by the customer by this nut, and for example by means of the above-mentioned measurement by the permanent magnet and the Hall sensor, can be adjusted e.g. in the simplest case manually to a very precise value.

Preferably, the transmission lever can be configured and arranged such that in a currentless starting position of the piezo actuator the plunger device is tensioned via the transmission lever against the piezo actuator so that an actuator engagement point of the piezo actuator close to the tilting axis on the transmission lever lies on a line or respectively plane with a roller bearing face of the shaft of the tilting axis with respect to the transmission lever and the spherical shells on the flange of the head sleeve part in the spherical caps remote from the tilting axis on the transmission lever.

This has the advantage that the piezo actuator in the starting position thus engages at a height of the tilting axis and of the contact point with respect to the plunger device on the transmission lever.

For example, the piezo actuator on the one hand can be supported in a stationary manner rigidly via a surface contact on the valve side. On the other hand, it can be tensioned on the lever side close to the tilting axis on the long lever arm of the transmission lever by a linear actuator engagement point parallel to the surface contact.

Preferably, the closure element, particularly preferably together with the fluidic unit, can be advantageously installed in the metering system directly by the customer himself in a detachable manner, in the sense of exchangeably, most particularly in a tool-free manner. This means that the closure element for example can only be coupled to the transmission element under pressure, or respectively can be in contact, so that it is able to be changed or respectively exchanged by the customer himself very easily and quickly, in particular in a tool-free manner. Installing the closure element in the metering system exchangeably in such a manner is therefore particularly advantageous, as the longevity of the metering system as a whole is improved, as it is the component of the metering system which, in operation of the metering system, is exposed to the greatest wear.

The invention is explained once again more closely in the following, with reference to the enclosed figures with the aid of example embodiments. Here, in the various figures, the same components are given identical reference numbers. The figures are generally not to scale and are to be understood merely as a schematic representation. There are shown:

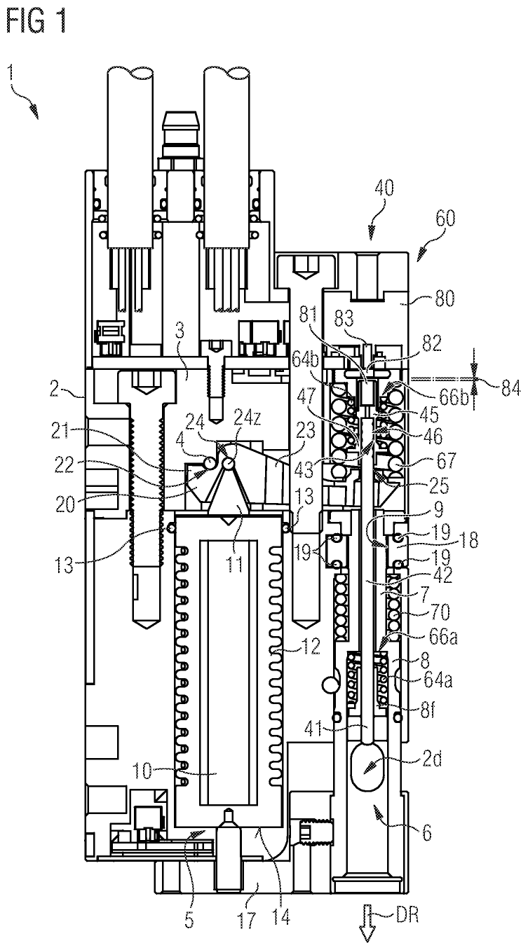

FIG. 1 a longitudinal section through an example embodiment of a metering system according to the invention with uncoupled fluidic unit and dismantled plunger, with a view into the interior of a housing which is illustrated partially opened,

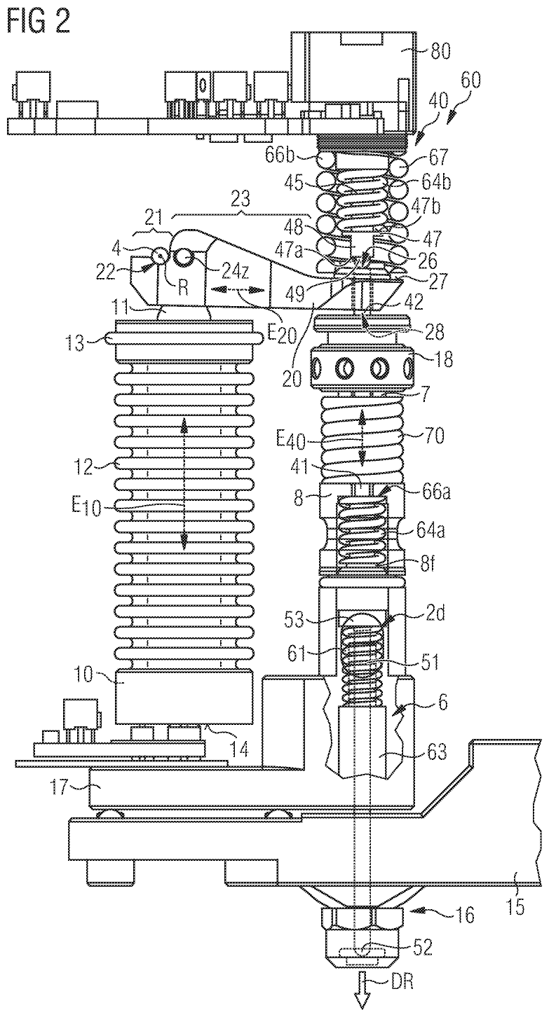

FIG. 2 a perspective side view onto the example embodiment of FIG. 1 with the most essential components for the metering mechanism (without housing, for clarity), but now with mounted plunger and coupled fluidic unit.

The figures show an example embodiment of a metering system 1 according to the invention. Belonging to the main components of this metering system 1 are a housing 2 with a piezo actuator 10 located therein, a fluidic unit 15 with a valve 16 (see FIG. 2), a plunger device 40 for closing the valve 16 and a transmission lever 20 or respectively lever 20 for coupling the piezo actuator 10 with the plunger device 40.

In general, the housing 2 of the metering system 1 can be described substantially as cuboid-shaped. FIG. 1 shows here a longitudinal section transversely through the metering system 1 with uncoupled fluidic unit (not illustrated in FIG. 1). FIG. 2 shows inter alia how and where the fluidic unit 15 of the metering system 1 is coupled to the remaining metering system 1.

In this respect, the housing 2 in the (here right-hand) lower corner has on the underside a coupling point for an elongated closure element 51 or respectively a plunger 51 of the plunger device 40 and for the said fluidic unit 15 with the valve 16. The closure element 51 or respectively the plunger 51 is part here of the fluidic unit 15 or respectively is installed into the latter and on changing of the fluidic unit 15 can be changed together with it.

As can be seen in FIG. 2, in the coupled state as intended, the plunger 16 sits in the valve 16 in a so-called valve seat or respectively sealing seat. In this position, it closes the valve 16 as needed, so that no metering medium can flow out or exit from the valve 16 unintentionally. At this point it is to be mentioned once again that relative directional information such as “top”, “bottom”, “above”, “below”, “upper side”, “lower side”, “lateral or respectively left/right”, “horizontal”, “vertical”, “front”, “rear” etc. refer here, as also in the entire document, arbitrarily to the illustration in the figures, although the metering system 1 in operation is typically used predominantly in the orientation illustrated in FIG. 1, i.e. mostly a metering onto a workpiece takes place with gravity, therefore in metering direction DR, therefore e.g. in the direction from the lever 20 to the valve 16 downwards.

On the upper side in the opposite (here left-hand) upper corner of the housing 2, several cables or respectively lines leave from the housing 2. Via these, the metering system can be connected for control, current supply etc. with a superordinate control unit (not illustrated here) and the latter in turn can be connected with a superordinate metering system.

In the housing 2 itself, the cylindrically encapsulated piezo actuator 10 is located in the lower half in the centre, as is further explained later. The latter is mounted on the lower side at its rear end on a flat surface contact 5 of the housing 2 with a planar or respectively flat support surface 14 and connected electrically via through-contacting bores. Through this mounting, the losses in the mounting region can be minimized. At the opposite, upper end, the piezo actuator 10 has a trapezoidal actuator front 11 running to the lever 20 lying thereabove, which actuator front stands or respectively engages at an actuator engagement point 24, sunk in the lever 20, in the interior of the lever 20 with the formation of a roller bearing 24 on a cylinder pin 24z running transversely or respectively horizontally through the lever 20. The cylinder pin 24z here is pressed securely into the lever 20, so that the piezo actuator 10 with its actuator front 11, which is adapted on the front side in a jaw-like manner or respectively concavely to the cylinder-shaped outer surface of the cylinder pin 24z, can roll on the cylinder pin 24z slightly laterally, therefore here to the right or respectively left—when, as provided for the exerting of a pulse onto the lever 20 by means of applying an electric voltage, it is extended upwards or in the opposite direction is compressed downwards again.

Here, the piezo actuator 10 itself is a hermetically encapsulated piezo actuator 10 i.e. it comprises a piezo stack, which apart from lines guided through the encapsulation 12, is surrounded by a “wave-shaped” encapsulation 12 of the piezo actuator 10, which in turn is surrounded by the housing 2 with some play in a hollow-cylindrical-shaped manner. Annularly around the upper side of the piezo actuator 10 beneath the actuator front 11, a ring seal 13 seals between encapsulation 12 and housing 2 and thus forms an intermediate space around the encapsulation 12, in which a cooling fluid can circulate for cooling the piezo actuator 10 in operation around the encapsulation 12. For this, this cooling fluid is introduced advantageously in a cool condition continuously at one side into the intermediate space, and is discharged again in a warm condition on the other side (not illustrated here), so that the piezo actuator 10 in any case does not exceed a certain maximum operating temperature.

As already mentioned, the lever 20 is located above the piezo actuator 10. This lever is mounted in the housing 2 via a cylindrical shaft 4, running horizontally (here into or respectively out from the plane of the drawing) transversely to the lever 20, which shaft represents or respectively embodies a tilting axis R, tiltably about the shaft 4 or respectively tilting axis R.

For this, the shaft 4 is fastened or respectively anchored in a stationary manner on the end side respectively fixedly in a lever bearing 3 or respectively lever bearing part of the housing 2, which lever bearing 3 surrounds the lever 20. The lever 20 is pressed or respectively tensioned by a pretensioning spring 67 of the spring arrangement 60 and the piezo actuator 10 from below against the shaft 4. In a starting position, it is thus aligned substantially horizontally.

A very short lever arm 21 extends from the eccentric or respectively decentral position of the shaft 4 or respectively tilting axis R in a longitudinal extent of the lever 2 (to the left here in the longitudinal section in FIG. 1), and a long lever arm 23 in relation thereto extends in the opposite direction (here to the right). The short lever arm 21 serves only as bearing 22 or respectively trough for the shaft 4, so that the eccentrically positioned shaft 4 which, as it were, is located almost at one end of the lever 20, can not slip to the side of the short lever arm 21 on the lever 20.

The long lever arm 23 has, close to the tilting axis, therefore close to the position of the shaft 4, the actuator engagement point 24 of the piezo actuator 10, and remote from the tilting axis, therefore at an end portion of the lever arm 23, has a plunger contact point 25. At the plunger contact point 25, the lever 20 can receive or respectively raise the plunger device 40—like a type of “shovel” with a “hole” 28 or respectively a through-opening 28 in the shovel surface in a surrounding manner on the inner edge of the hole 28—substantially perpendicularly to its extent direction E₂₀.

The pretensioning spring 67 already mentioned further above, here a large compression coil spring 67 with a larger inner diameter relative to the hole 28, stands for pretensioning of the lever 20 against the piezo actuator 10 around the hole 28 along a hole edge 27 of the hole 28 or respectively at a pretensioning contact point 27 on the upper side at the shovel surface of the lever 20.

The illustrated arrangement is particularly compact, as the plunger device 40 runs through the hole 28 of the lever 20 (substantially perpendicularly to the extent direction E₂₀ of the lever 20) very close to the piezo actuator 10 in an extent direction E₄₀ substantially parallel to an extent direction E₁₀ of the piezo actuator 10 in the housing 2. In other words, the piezo actuator 10 and the plunger device 40 are therefore arranged in a particularly compact manner adjacent to one another vertically in the housing 2 substantially in the same extent direction E₁₀, E₄₀ and connected to one another here via the relatively short lever 20 and therefore only spaced a little from one another.

The plunger contact point 25, at which the lever 20 directly engages under and raises the plunger device 40 (here from below on an opening movement of the valve 16, as is additionally explained further below), has a surface with two recessed spherical caps 26, which receive corresponding spherical shells 49 of the plunger device 40 as it were in an interlocked manner, as is also additionally explained further below.

The plunger device 40 itself consists here of two rod elements 41, 51, which in the state of the metering system 1 when ready for operation are tensioned with respect to one another by means of the already mentioned spring arrangement 60. In this state of readiness to operate, the fluidic unit 15 is coupled with the housing 2 of the metering system, as is the case in FIG. 2.

The (here upper) first rod element 41 or respectively transmission element 41 of the plunger device 40 consists in turn of two separately produced parts 42, 45, namely an elongated rod part 42 with a rod with a cylindrical outer surface, and an elongated head sleeve part 45 with a hollow-cylindrical cylinder body and a broader head. The two parts 42, 45 are pressed to one another for mounting, i.e. the rod part 42 is fixed for this with an end portion internally in the hollow-cylindrical head sleeve part 45 in a customized stationary manner, i.e. by means of thermal shrinking.

For the form-fitting connection with the head sleeve part 45, the rod of the rod part 42 has on the outer surface in the region of the end portion, which is introduced or respectively inserted internally into the head sleeve part 45, radially outwardly projecting annular grooves or respectively flutes 43.

Corresponding thereto, the head sleeve part 45 of the transmission element 41 has radially inwardly protruding annular springs 46, which in the connected state of the two parts 42, 45 engage at least in a slightly form-fitting manner into the annular grooves 43 or respectively flutes 43. The annular grooves 43 and annular springs 46 of the two parts 42, 45 could alternatively also concern corresponding inner- and outer threads, which can be screwed into one another in order to connect the two parts 42, 45 to one another in a form-fitting manner.

The head of the head sleeve part 45 constitutes a flange 47 which is wider relative to the 5 remaining head sleeve part 45. The flange 47, viewed in axial direction of the head sleeve part 45, has two different surfaces 47a, 47b. On the valve side (viewed in axial direction), it comprises a first flange surface 47a, which is formed by a cuboid-shaped bearing block 48. Facing away from the valve, it has a circular disc-shaped second flange surface 47b.

One of the closure springs 64b or respectively smaller compression coil springs 64b of the spring arrangement 60 for closing the valve 16 (which are additionally explained further below) stands at the round flange surface 47b facing away from the valve. The compression coil spring 64b surrounds the internal cylinder body of the head sleeve part 45 here in an annular manner.

On the rear side, i.e. on the valve side, the said bearing block 48 projects from the second flange surface 47b, facing away from the valve, in a flange-like manner, here in the form of a “chordal quadrilateral” with respect to the circular disc-shaped flange surface 47b. It has the two spherical shells 49 (already mentioned above), projecting in a hemispherical 20 manner in the direction of the lever 20. These roll, in operation, on the corresponding spherical caps 26 (likewise already mentioned above), formed or respectively recessed in the lever 20 at the plunger contact point 25. The head sleeve part 45 of the plunger device 40 is thus as it were “interlocked” with the lever 20 with the formation of a low-friction friction point.

The second rod element 51 (the lower here in FIG. 2) or respectively closure element 51 of the plunger device 40, also abbreviated in the following as plunger 51, is in one piece. It has an elongated, cylindrical body or respectively shank, which at the lower end—which end in the installed state as intended faces the valve 16—is formed with a plunger tip 52 30 and at the opposite upper end with a plunger head 53. The plunger head 53 concerns an annular flange, therefore an annular widening or respectively a ring with a wider outer diameter than at the remaining body or respectively shank of the plunger 51. The plunger tip 52 concerns here for example a rounded front of the plunger 51. The plunger 51 could for example also concern, however, differently from as is illustrated here, a so-called 35 “valve push rod”, as is described specifically in the publication DE 10 2020 121 777. In this respect, the content thereof is incorporated here.

On the upper side, i.e on the lever side of the plunger 51, the transmission element 41, already described above, stands at the plunger head 53.

At this point it is to be mentioned that the housing 2, as can be readily seen in FIG. 1, in the region or respectively approximately at the height of the plunger head 53 of the plunger 51, has a here slightly oval drainage opening 2d. In the case of a leakage of the metering medium which is to be metered, this makes provision that the metering medium can not arrive or respectively be pressed into the drive region of the metering system 1 located above the plunger 51 from the nozzle chamber of the fluidic unit 15, located therebeneath, in the region of the plunger tip 53, but can previously already flow out from the metering system 1 out of this drainage opening 2d at an advantageously selected point of the metering system 1. At the same time, the size of the drainage opening 2d enables an easy, therefore readily visible optical checking of this region.

As already partly described, the plunger device 40 is mounted resiliently in itself by means of a spring arrangement 60 or respectively tensioned with respect to one another. For this, the spring arrangement 60 has, on the one hand, three smaller compression coil springs 61, 64a, 64b, substantially identical in construction, with substantially the same outer diameters, wherein the compression coil springs 64a, 64b constitute a closure spring arrangement 64a, 64b, and the compression coil spring 61 constitutes an opening spring arrangement 61.

Two of the compression coil springs 64a, 64b or respectively closure springs 64a, 64b are arranged so that their elastic force presses the plunger device 40 in the direction of the valve 16, in order to close the valve 16, by ultimately pressing the plunger 51 of the plunger device 40 into a closed valve position into the so-called valve seat.

The lower closure spring 64a of the two closure springs 64a, 64b is arranged here above the plunger head 53 of the plunger 51 within a second housing sleeve portion 8 of a housing sleeve 6 of the housing 2, and acts indirectly via a guide sleeve 8f from above onto the plunger head 53 of the plunger 51. Here, the closure spring 64a surrounds the shank or respectively cylindrical body of the rod part 42 of the transmission element 41 with some play, and is supported on the upper side against a constriction 66a or respectively an edge 66a of a first housing sleeve portion 7 of the housing sleeve 6, lying closely with relatively close surrounding play at the shank of the rod part 42, in which housing sleeve the plunger device 40 is mounted.

The transmission element 41 is additionally pressed downwards against the closure element 51 in the direction of the valve 16 by the upper closure spring 64b of the two closure springs 64a, 64b—which in fact as already described is mounted above a flange 47 of the head sleeve part 45 and rests against a part 66b of the housing 2 thereabove.

The third, remaining (smaller) compression coil spring 61 or respectively opening spring 61 is arranged directly beneath the plunger head 53 of the plunger 51 and presses against the plunger head 53, by resting at the lower end against a guide sleeve 63, which guides the plunger 51 axially when, as illustrated in FIG. 2, it is coupled substantially together with the fluidic unit 15 and the valve 16 with the remaining metering system 1.

In total thus two compression coil springs 64a, 64b press downwards and one compression coil spring 61 presses upwards, so that the valve 61 is normally, i.e. in the currentless state of the metering system 1, closed solely by the imbalance of forces.

When the lever 20 in operation then presses by a pulse of the piezo actuator 10 against the head sleeve part 45 and moves the latter against the pressure of the closure springs 64a, 64b of the spring arrangement 60 together with the rod part 42 away from the valve 16, it frees somewhat the plunger 51 located therebeneath, in a closing valve seat. Through the elastic force of the closure springs 64a 64b being undertaken here by the lever 20, temporarily no or at least a smaller elastic force counteracts the opening spring 61, so that the opening spring 61 can press the plunger 51 out from the valve seat upwards into an opened valve position.

Additionally to the spring arrangement 60, the metering system 1 also has a coupling spring 70. This serves for the manual adjusting possibility of the nozzle-plunger distance by the customer, when e.g.: the fluidic unit 15 with the desired valve 16 and with the appropriate plunger 51 (which, as stated, can be part of the fluidic unit 15) are mounted on the remaining metering system 1. For this, the metering system 1 has a coupling nut 18 at the fluidic unit 15, which can be screwed onto a thread 9 on the fluidic unit 15 or respectively housing sleeve 6 of the housing 2, in order to couple the fluidic unit 15 with the remaining metering system 1. The coupling nut 18 can be tightened here against the elastic force of the coupling spring 70 and thus the nozzle-plunger distance can be adjusted more precisely. For this, the coupling spring 70 has an inner diameter which is greater than the outer diameter of the first housing sleeve portion 7, but smaller, in particular approximately equal in size, as the outer diameter of the second housing sleeve portion 8. The coupling spring 70 lies on an upper side of the second housing sleeve portion 8 and stands above at the coupling nut 18. It thus surrounds in a fitting manner the first housing sleeve portion 7 and rests at the second housing sleeve portion 8 downwards in the direction of the valve 15. So that at the coupling point of the coupling nut 18 above the coupling spring 70 no fluid, such as e.g. metering medium, can penetrate into the housing part, therefore inter alia the frame surrounding or respectively receiving the piezo actuator thereabove, this is sealed twice by means of two ring seals 19, above and below.

Furthermore, the metering system 1 also comprises a fluidic positioning 17 for the positioning of the fluidic unit 15, which fluidic positioning 17 is optionally heatable with a corresponding control. This serves to heat the metering medium, the fluidic unit 15 with the valve 16 and/or the plunger 51 in the valve 16.

At the opposite upper end of the housing 2 of the metering system 1 above the plunger device 40, tensioned with the spring arrangement 60 with respect to one another, a magnetic shield 80 is located as part of the housing 2. The magnetic shield 80 shields magnetically outwards in particular upwards, a Hall sensor arrangement with a first permanent magnet 81, a Hall sensor 82, spaced apart therefrom by a gap 84, and a second permanent magnetic 83 above the first permanent magnet 81.

A part of the housing 2 in the region of the lever bearing 3 serves as further magnetic shield beneath the magnetic shield 80, in order to also magnetically shield the Hall sensor arrangement downwards. As a whole, the Hall sensor arrangement is thus protected against external influences, so that the Hall sensor can measure as precisely as possible in an undisturbed manner. This is because the Hall sensor serves to adjust the plunger-nozzle distance very accurately, and in operation to also be able to monitor it as a type of “feedback system”. Thus for example in operation the movement of the plunger can be brought in correlation with the control voltage and, if applicable, the control voltage can be readjusted or else a warning message can be generated when the measured value is located outside a previously defined target range and, for instance, the intervention of an operator becomes necessary. This is achieved by a distance of the first permanent magnet 81, which is inserted as a small rod-shaped permanent magnet 81 into the upper sleeve end of the heat sleeve part 45, with respect to the Hall sensor 82 being detected by the Hall sensor 82 in the form of an absolute magnetic field measurement. When a defined valve is measured, an ideal desired distance or respectively gap 84 is present. Accordingly, the plunger 51 is then also located at the other end of the plunger device 40 in a desired position, therefore a desired plunger-nozzle distance with respect to the valve 16 or respectively to the nozzle 16. The second permanent magnet 83, which is fastened above the Hall sensor 82 on a side of the Hall sensor 82 facing away from the first permanent magnet 81, and arranged so that its magnetic field acts counter to the magnetic field of the first permanent magnet, serves here to displace the magnetic field such that the measurement range of the Hall sensor 82 can be fully utilized. This means that the measurement range of the Hall sensor 82, which is normally divided to a positive and a negative range, is displaced as completely as possible into the positive or into the negative range, in order to thus increase the sensitivity of the Hall sensor 82.

Finally, it is pointed out once again that the preceding device, described in a detailed manner, merely concerns an example embodiment, which can be modified by the specialist in the art in a variety of ways, without departing from the scope of the invention. For example, several metering systems could be arranged in a metering system. Furthermore, the use of the indefinite article “a” or respectively “an” does not rule out that the respective features can also be present several times.

### LIST OF REFERENCE NUMBERS

1 metering system
2 housing
2d drainage opening
3 lever bearing of the housing
4 shaft
5 surface contact of the housing for the piezo actuator
6 housing sleeve
7 first housing sleeve portion
8 second housing sleeve portion
8f guide sleeve in the second housing sleeve portion for guiding the closure spring
9 thread
10 piezo actuator
11 piezo actuator front
12 encapsulation
13 ring seal
14 support surface
15 fluidic unit
16 valve/nozzle
17 fluidic positioning
18 coupling nut of the fluidic unit
19 ring seals for the coupling nut
20 transmission lever/lever
21 short lever arm
22 bearing for shaft
23 long lever arm
24 actuator engagement point/roller bearing, close to tilting axis
24z cylinder pin of the actuator engagement point
25 plunger contact point, remote from tilting axis
26 spherical caps
27 pretensioning spring contact point/plate-shaped part of the transmission lever
28 hole/through-opening of the transmission lever for the rod part
40 plunger device
41 first rod element/transmission element
42 rod part of the transmission element
43 annular grooves of the rod part
45 head sleeve part of the transmission element
46 annular springs of the head sleeve part
47 flange of the head sleeve part
47a first flange surface, valve side
47b second flange surface
48 bearing block
49 spherical shells
51 second rod element/closure element/plunger
52 plunger tip of the plunger/closure element of the plunger device
53 plunger head
60 spring arrangement
61 opening spring arrangement/opening spring/compression coil spring
63 guide sleeve for the closure element
64a, b closure spring arrangement/closure springs/compression coil springs
66a constriction/edge of the housing
66b part of the housing
67 pretensioning spring/compression coil spring
70 coupling spring
80 shield
81 first permanent magnet
82 Hall sensor/Hall probe
83 second permanent magnet
84 gap
DR metering direction/direction from the transmission lever to the valve
E₁₀ extent direction of the piezo actuator
E₂₀ extent direction/lever arm longitudinal direction of the transmission lever
E₄₀ extent direction of the plunger device
R tilting axis through the shaft

1. A metering system (1) with
a housing (2),
a piezo actuator (10) located therein,
a fluidic unit (15) with a valve (16),
a plunger device (40) for closing the valve (16)
and a transmission lever (20) for coupling the piezo actuator (10) to the plunger device (40),
wherein the piezo actuator (10) is arranged substantially parallel next to the plunger device (40) in the housing (2), wherein the piezo actuator (10) extends away from the transmission lever (20) substantially in the direction of a side facing the valve (16).

2. The metering system according to claim 1, wherein the transmission lever (20) extends transversely to an extent direction (E₁₀) of the piezo actuator (10) and an extent direction (E₄₀) of the plunger device (40)
and/or
wherein the piezo actuator (10) is tensioned relative to the housing (2) via the transmission lever (20) with the plunger device (40) by means of a spring arrangement (60).

3. The metering system according to claim 1, wherein the plunger device (40) is formed from at least two rod elements (41, 51), which are tensioned with respect to one another, wherein preferably the plunger device (40) comprises on the lever side a transmission element (41) as a first rod element (41), and on the lever side a closure element (51) as a second rod element (51).

4. The metering system according to claim 2, wherein the spring arrangement (60) has several springs (61, 64a, 64b, 67), preferably compression coil springs (61, 64a, 64b, 67) for the sprung tensioning of the plunger device (40), particularly preferably an opening spring arrangement (61) for opening the valve (16) and a closure spring arrangement (64a, 64b), which has a greater spring rate and/or pretensioning force relative to the opening spring arrangement (61), particularly preferably at least two closure springs (64a, 64b) operating in the same direction, but contrary to the opening spring arrangement (61), for closing the valve (16).

5. The metering system according to claim 4, wherein the opening spring arrangement (61) fits the closure element (51) resiliently in the housing (2) such that a force acts on the closure element (51), in order to bring the closure element (51) in the direction of an opened valve position,
and wherein the closure spring arrangement (64a, 64b) tensions the transmission element (41) resiliently in the housing (2) such that a contrary force acts on the transmission element (41), in order to bring the transmission element (41) against the closure element (51) and thus to bring the closure element (51) in the direction of a closed valve position.

6. The metering system according to claim 3, wherein the transmission element (41) has two parts (42, 45) which are able to be coupled to one another, preferably a rod part (42) and a head sleeve part (45),
wherein preferably an elongated rod part (42) of the transmission element (41) stands on the valve side at the closure element (51) and extends from there, preferably through a through-opening (28) in the transmission lever (20), up to a head sleeve part (45) on the other side of the transmission lever (20),
and/or
wherein preferably the head sleeve part (45) has a flange (47), at which the transmission lever (20) stands on the valve side.

7. The metering system according to claim 6, wherein the rod part (42) of the transmission element (41) is guided axially on the valve side parallel to the piezo actuator (10) in a first housing sleeve portion (7) of a housing sleeve (6) of the housing (2) with relatively close radial surrounding play,
whereas the head sleeve part (45) of the transmission element (41) facing away from the valve is guided with relatively wide radial surrounding play.

8. The metering system according to claim 6, wherein one of the closure springs (64b) of the spring arrangement (60) stands at the head sleeve part (45) on a flange surface (47b) of the flange (47) facing away from the valve.

9. The metering system according to claim 6, wherein the flange (47) of the head sleeve part (45) has spherical shells (49) protruding in a hemispherical manner on the valve side, which form a bearing (26, 49) together with corresponding spherical caps (26), which are formed, preferably recessed, for this on the transmission lever (20).

10. The metering system according to claim 1, wherein a first permanent magnet (81) is fastened on the plunger device (40), preferably on the head sleeve part (45) of the transmission element (41)
and wherein in the housing (2) a Hall sensor (82) is arranged lying opposite, spaced apart by a gap (84) with respect to this permanent magnet (81).

11. The metering system according to claim 10, wherein on a side of the Hall sensor (82) facing away from the first permanent magnet (81) a second permanent magnet (83) is arranged, wherein the second permanent magnet (83) has a counter magnetic field opposed to the first permanent magnet (81)
and/or
wherein a surrounding region around the Hall sensor (82), preferably including the second permanent magnet (83), is magnetically shielded at least on the sides facing away from the first permanent magnet (81) by means of a shield (80).

12. The metering system according to claim 7, wherein a housing sleeve (6) is mounted adjustably in position relative to the surrounding housing (2) of the metering system (1) for adjusting a distance between valve (16) and closure element (51).

13. The metering system according to claim 1, wherein the transmission lever (20) is fitted in a tiltable manner on a tilting axis (R) in the form of a shaft (4) on a side facing the piezo actuator (10), which shaft (4) in turn is respectively fastened at the end side in a lever bearing (3),
wherein the piezo actuator (10) for opening the valve (16) stands close to the tilting axis at an actuator engagement point (24) at right angles to the tilting axis (R) at the transmission lever (20) with the formation of a roller bearing.

14. The metering system according to claim 13, wherein the transmission lever (20) is configured and arranged such that in a currentless starting position of the piezo actuator (10) the plunger device (40) is tensioned via the transmission lever (20) against the piezo actuator (10) so that an actuator engagement point (24) of the piezo actuator (10) at the transmission lever (20) lies on a line with a roller bearing surface of the shaft (4) of the tilting axis (R) to the transmission lever (20) and the spherical shells (49) at the flange (47) of the head sleeve part (45) in the spherical caps (26) at the transmission lever (20).

15. The metering system according to claim 3, wherein the closure element (51), preferably together with the fluidic unit (15), is installed detachably in the metering system (1).
